(19) United States
(12) Patent Application Publication
(10) Pub. No.: US 2023/0357921 A1
(43) Pub. Date: Nov. 9, 2023

(54) DEPOSITION RATE ENHANCEMENT OF AMORPHOUS CARBON HARD MASK FILM BY PURELY CHEMICAL MEANS

(71) Applicant: Lam Research Corporation, Fremont, CA (US)

(72) Inventors: Matthew Scott Weimer, Portland, OR (US); Ragesh Puthenkovilakam, Portland, OR (US); Kapu Sirish Reddy, Portland, OR (US); Chin-Jui Hsu, Portland, OR (US)

(21) Appl. No.: 18/247,060

(22) PCT Filed: Sep. 27, 2021
(86) PCT No.: PCT/US2021/052250

§ 371 Date: Mar. 28, 2023

Related U.S. Application Data
(60) Provisional application No. 63/198,108, filed on Sep. 29, 2020.

(51) Int. Cl. C23C 16/04

(52) U.S. Cl. CPC C23C 16/042

(57) ABSTRACT

Provided herein are methods and related apparatus for depositing an ashable hard mask (AHM) on a substrate at high temperatures using an additive that reduces a competing etch process. Sulfur hexafluoride may be used to improve the deposition rate of the AHM with minimal changes to the properties of the resulting film.

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Amorphous carbon films may be used as hard masks and etch stop layers in semiconductor processing, including in memory and logic device fabrication. These films are also known as ashable hard masks (AHMs) because they may be removed by an ashing technique. As aspect ratios increase, particularly for 3D NAND applications, AHMs require higher etch selectivity and/or thickness. Current methods of forming highly selective AHMs using plasma enhanced chemical vapor deposition (PECVD) processes are time consuming to achieve a desired thickness, increasing the cost of ownership.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Disclosed herein are methods and systems of depositing an amorphous carbon film. In one aspect of the embodiments herein, a method of forming an ashable hard mask (AHM) film is provided, the method including: exposing a substrate to a process gas including a hydrocarbon precursor gas and deposition enhancer molecule; and depositing on the substrate the AHM film by a plasma enhanced chemical vapor deposition (PECVD) process using the process gas. In some embodiments, the hydrocarbon precursor is propylene. In some embodiments, the volumetric flow ratio of deposition enhancer molecule to hydrocarbon precursor is between about 0.01 to about 0.5. In some embodiments, the AHM is deposited at a rate greater than about 0.45 μm/min. In some embodiments, further including forming HF during depositing the AHM film.

In some embodiments, the process gas further includes an inert gas. In some embodiments, the inert gas is one or more of helium, argon, and nitrogen. In some embodiments, the process gas consists essentially of the hydrocarbon precursor, deposition enhancer molecule, and the inert gas. In some embodiments, the semiconductor substrate is positioned on a pedestal while depositing the AHM film, and the pedestal has a temperature between about 20° C. and about 750° C. In some embodiments, the deposition enhancer molecule inhibits an etch process resulting from hydrogen radicals and/or ions bonding with carbon atoms in the deposited AHM. In some embodiments, the deposition enhancer molecule does not cause etching of the AHM film.

In some embodiments, the AHM is between about 1 μm and about 2 μm thick. In some embodiments, the PECVD process includes igniting a plasma generated by a dual radio frequency (RF) plasma source including a high frequency (HF) component and a low frequency (LF) component. In some embodiments, the HF component has a power of about 50 to about 8000 W. In some embodiments, the LF component has a power of about 0 to about 6000 W. In some embodiments, the PECVD process is performed at a pressure of about 1 to about 11 Torr.

In some embodiments, the AHM has a modulus of about 43 to 90 GPa. In some embodiments, the AHM has a hardness of about 5.3 to about 8.5 GPa. In some embodiments, the AHM has an internal stress of about −100 to about −550 MPa. In some embodiments, the AHM has an extinction coefficient of about 0.45 to about 0.65. In some embodiments, the AHM has a refractive index of about 1.9 to about 2.2. In some embodiments, the AHM includes mostly carbon. In some embodiments, the AHM has a hydrogen content of at most about 10% atomic.

In another aspect of the embodiments herein, an apparatus for forming an ashable hard mask (AHM) film is provided, the apparatus including: one or more process chambers, each process chamber including a substrate support; one or more gas inlets into the process chambers and associated flow-control hardware; and one or more processors configured to: expose a substrate in one of the one or more process chambers to a process gas including a hydrocarbon precursor gas and deposition enhancer molecule; and deposit on the substrate the AHM film by a plasma enhanced chemical vapor deposition (PECVD) process using the process gas. In some embodiments, the hydrocarbon precursor is propylene. In some embodiments, the volumetric flow ratio of deposition enhancer molecule to hydrocarbon precursor is between about 0.01 to about 0.5. In some embodiments, the AHM is deposited at a rate greater than about 0.45 μm/min. In some embodiments, further including forming HF during depositing the AHM film.

In some embodiments, the process gas further includes an inert gas. In some embodiments, the inert gas is one or more of helium, argon, and nitrogen. In some embodiments, the process gas consists essentially of the hydrocarbon precursor, deposition enhancer molecule, and the inert gas. In some embodiments, the semiconductor substrate is positioned on a pedestal while depositing the AHM film, and the pedestal has a temperature between about 100° C. and about 750° C. In some embodiments, the deposition enhancer molecule inhibits an etch process resulting from hydrogen radicals and/or ions bonding with carbon atoms in the deposited AHM. In some embodiments, the deposition enhancer molecule does not cause etching of the AHM film. In some embodiments, the AHM is at least about 1.5 μm thick. In some embodiments, the PECVD process includes igniting a plasma generated by a dual radio frequency (RF) plasma source including a high frequency (HF) component and a low frequency (LF) component. In some embodiments, the HF component has a power of about 50 to about 8000 W. In some embodiments, the LF component has a power of about 0 to about 6000 W. In some embodiments, the PECVD process is performed at a pressure of about 1 to about 11 Torr.

In some embodiments, the AHM has a modulus of about 43 to 90 GPa. In some embodiments, the AHM has a hardness of about 5.3 to about 8.5 GPa. In some embodiments, the AHM has an internal stress of about −100 to about −550 MPa. In some embodiments, the AHM has an extinction coefficient of about 0.45 to about 0.65. In some embodiments, the AHM has a refractive index of about 1.9 to about 2.2. In some embodiments, the AHM includes mostly carbon. In some embodiments, the AHM has a hydrogen content of at most about 10% atomic.

These and other features of the disclosed embodiments will be described in detail below with reference to the associated drawings.

### BRIEF DESCRIPTION OF DRAWINGS

FIG. 1 presents a flow diagram of operations for one example embodiment.

FIG. 2 presents schematic illustrations of etching stacks of alternating layers in one example embodiment.

FIG. 3 presents deposition rate as a function of SF₆ to C₃H₆ ratio.

FIGS. 4-6 present charts of various film properties as a function of SF₆ to C₃H₆ ratio.

FIGS. 7 and 8 present FTIR spectra according to various embodiments herein.

FIGS. 9-11 are schematic diagrams of examples of process chambers for performing methods in accordance with disclosed embodiments.

### DETAILED DESCRIPTION

### Introduction and Context

Semiconductor device processing involves formation of multi-layer stacks which may be used for fabrication of various three-dimensional devices such as 3D NAND structures. Some stacks include multiple alternating layers of dielectric and conducting material, each layer of which may be about 10 nm or thicker. One approach to forming such stacks involves deposition of multiple alternating layers of oxide and nitride material (ONON multiple layer deposition), followed by selective removal of material and backfill deposition of metal into spaces where the nitride material previously occupied. Another approach is to directly pattern a stack of multiple, alternating layers of oxide and polysilicon (or “poly” as used elsewhere herein) where polysilicon remains as the conducting layer. These methods may be used to fabricate 3D NAND structures.

Etching of the stack may be performed using a patterned amorphous carbon film. An amorphous carbon film may also be referred to as an ashable hard mask (AHM). The amorphous carbon layer may be suitable as a hard mask that has a high selectivity during an etch process of the stack. High selectivity is determined in the context of a particular etch chemistry. For a particular etch chemistry, the underlying substrate, e.g., the ONON layers, etches much faster than a hard mask, e.g., an amorphous carbon layer. For various applications described herein the underlying substrate contains silicon oxide, silicon nitride, and/or polysilicon.

For 3D NAND applications, ashable hard masks may be carbon based and more than about 1.5 micrometers thick. Such thicknesses may be necessary for applications that require etching high aspect ratio features such as those used to form some memory devices such as 3D NAND devices. Sometimes, or in certain embodiments, applications using amorphous carbon hard masks produced as described herein etch a stack of alternating layers of silicon oxide and silicon nitride or a stack of alternating layers of polysilicon and silicon oxide. A large contributor to the costs in 3D NAND is the time to deposit AHMs, which, at a rate of about 0.25 micrometers/min and a 2 μm thick target layer, may take 8+ minutes to deposit. Thus, it is desirable to increase the deposition rate of the AHM with minimal change to the film properties, in particular without reducing the etch selectivity.

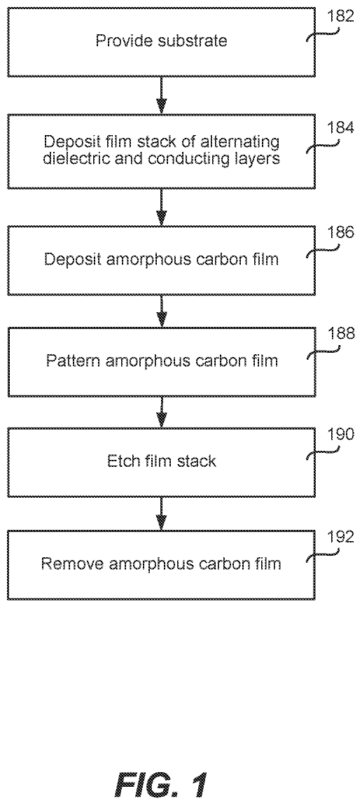

FIG. 1 shows a process flow diagram of operations performed in accordance with a method for forming a 3D NAND structure. In operation 182, a substrate is provided. In various embodiments, the substrate is a semiconductor substrate. The substrate may be a silicon wafer, e.g., a 200-mm wafer, a 300-mm wafer, or a 450-mm wafer, including wafers having one or more layers of material, such as dielectric, conducting, or semi-conducting material deposited thereon. In operation 184, a film stack of alternating dielectric and conducting layers is deposited on the substrate. In some embodiments, the dielectric layer is an oxide layer. In various embodiments, the oxide layer deposited is a silicon oxide layer. In various embodiments, the conducting layer is a nitride layer, e.g., a silicon nitride layer. In some embodiments, the conducting layer is a polysilicon layer. Each dielectric and conducting layer is deposited to about the same thickness, such as between about 10 nm and about 100 nm, or about 350 Å in some embodiments. The oxide layers may be deposited at a deposition temperature of between about room temperature and about 600° C. It will be understood that “deposition temperature” (or “substrate temperature”) as used herein refers to the temperature that the pedestal holding the substrate is set to during deposition.

Oxide and conducting layers for forming the alternating oxide and nitride film stack may be deposited using any suitable technique, such as atomic layer deposition (ALD), plasma enhanced atomic layer deposition (PEALD), chemical vapor deposition (CVD), plasma enhanced chemical vapor deposition (PECVD), physical vapor deposition (PVD), or sputtering. In various embodiments, the oxide and nitride layers are deposited by PECVD.

The film stack may include between 48 and 512 layers of alternating dielectric and conducting layers, whereby each dielectric or conducting layer constitutes one layer. In some embodiments, the film stack may include less than 48 layers, or greater than 512 layers of alternating dielectric and conducting layers, depending on the application. The film stack including the alternating oxide and nitride layers may be referred to as an ONON stack. While the film stack described may involve alternating oxide and nitride layers, it will be understood that additional layers may also be included in the stack, and further that other materials may be used for alternating layers that are not oxide and not nitride layers. For example, in some cases, a silicon germanium layer may be used in lieu of a nitride or silicon nitride layer. Other additional layers that may be on the stack include silicon-containing layers, germanium-containing layers, or both. Example silicon-containing layers include doped and undoped silicon carbide layers, doped and undoped polysilicon layers, amorphous silicon layers, doped and undoped silicon oxide layers, and doped and undoped silicon nitride layers. Dopants may include non-metal dopants. For example, doped silicon carbide layer is an oxygen-doped silicon carbide. In another example, doped silicon carbide layer is a nitrogen-doped silicon carbide. Further discussion of depositing and etching layers for 3D NAND applications may be found in Application PCT US2019/050369, filed Sep. 10, 2019, which is incorporated by reference herein for all purposes.

In operation 186, an amorphous carbon film is formed on the substrate. The amorphous carbon film has various properties described herein that make it suitable as a mask for etching the underlying substrate. For certain applications, the film is at least about 1 μm thick. In certain embodiments, the film is at least about 1.5 μm thick. In certain embodiments, the film is at least about 2 μm thick. In some embodiments, the film is between about 1 μm and about 2 μm thick. In operation 188, the amorphous carbon film is patterned such that portions of the underlying substrate are exposed. Patterning may be accomplished by, e.g., a lithography process.

In operation 190, the film stack is etched. The etch chemistry used is selective to the amorphous carbon film compared to the underlying substrate, such that the amorphous carbon film is etched at a lower rate than the layers of the film stack. Examples of etches can include radical and/or ionic-based etches. Examples of etch chemistries can include halogen-based etch chemistries such as fluorine-containing, bromine-containing, and chlorine-containing etch chemistries. For example, capacitively-coupled plasmas generated from fluorocarbon-containing process gases may be used to selectively etch oxide layers. Specific examples of process gases include CₓF_{y}-containing process gases, optionally with oxygen (O₂) and an inert gas, such as C₄H₈/CH₂F₂/O₂/Ar. In certain embodiments, an amorphous carbon layer is used as a hard mask in an etch process in which etch species are generated in a plasma.

Finally, in operation 192 the amorphous carbon film is removed, for example by a technique referred to as ashing, plasma ashing, or dry stripping. Ashing may be performed by an oxygen-rich dry etch. Often, oxygen, in the form of, e.g., O₂, N₂O, and NO, is introduced in a chamber under vacuum and RF power creates oxygen radicals in plasma to react with the AHM and oxidize it to water (H₂O), carbon monoxide (CO), and carbon dioxide (CO₂). Optionally, any remaining AHM residue may also be removed by wet or dry etching processes after ashing. The result is a patterned substrate layer.

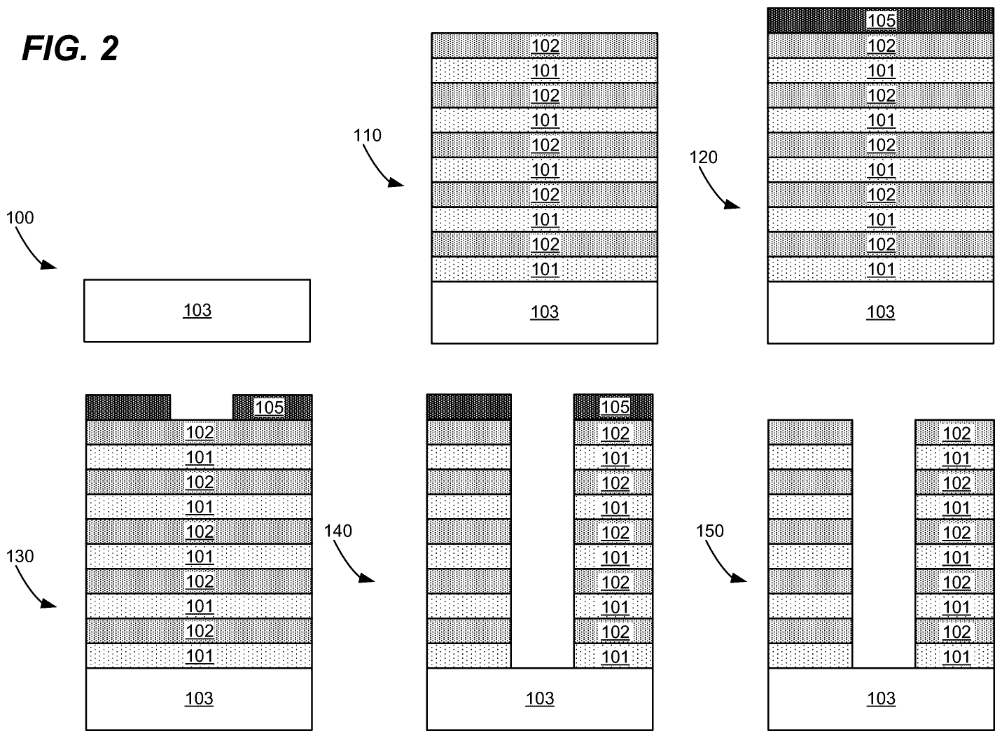

FIG. 2 provides schematic illustrations 100-150 of operations 182-192 of FIG. 1. In diagram 100, a substrate 105 is provided. Substrate 105 may be a silicon wafer having one or more layers previously formed thereon. In diagram 110, alternating layers of oxide (101) and nitride (102) films are deposited on the substrate 105. Note that while the structure shown in FIG. 2 shows an oxide deposited first, followed by nitride, oxide, nitride, etc., nitride may be deposited first, followed by oxide, nitride, oxide, etc.

In diagram 120, an amorphous carbon film 105 is deposited on top of the stack of oxide and nitride films. Details of this process are discussed further herein. In diagram 130, the amorphous carbon film 105 is patterned to expose portions of the underlying stack. The exposed portions of the amorphous carbon film 105 define regions where high aspect ratio features will be etched. In diagram 140, the underlying stack is etched, using the amorphous carbon film 105 as a mask, to form various features in the stack of alternating layers. In diagram 150, the amorphous carbon film 105 is removed, resulting in an etched stack of alternating layers of oxide and nitride films having various features.

In some embodiments, features to be etched using an AHM as described herein may have an aspect ratio of about 10:1 to 1000:1. In some embodiments, an opening size of the features may include about 20-100 nm across.

### Deposition Process

Certain processes for depositing amorphous carbon hard masks employ a carbon precursor, which may be a hydrocarbon such as propylene. In some cases, a hydrocarbon precursor has a relatively high carbon to hydrogen ratio. In some embodiments, propylene is an advantageous carbon precursor due to a lower tendency to polymerize and clog holes in showerheads and deposit on sensitive components of a deposition chamber. Propylene may also be advantageous for safety concerns at the higher pressures and temperatures employed for processes as described herein.

In addition to propylene or other suitable carbon containing precursor, the process may employ an inert or chemically unreactive gas such as argon, helium, nitrogen, or a combination of any of these.

While conventional processes may produce high quality amorphous carbon layers, they produce such films relatively slowly, at a rate of, for example, about 0.25 μm per minute. When depositing a relatively thick film such as is required for some of the high aspect ratio etch applications described herein (e.g., those requiring a hard mask thickness of 1.5 micrometers or greater), this relatively slow rate of deposition can have a negative impact on the throughput of the process, and therefore increase costs. Therefore, it may be desirable to employ a process that produces a comparably high-quality layer but does so more quickly.

One way to deposit the layer more quickly is to increase the flow rate of the reactants in the process gas, notably the propylene or other carbon containing precursor. However, simply increasing the flow rate does not necessarily create a film of suitable properties such as high density, good etch selectivity, low hydrogen content, and suitable mechanical properties that are desirable in an amorphous carbon hard mask for etching high aspect ratio features. Therefore, while increasing the carbon precursor flow rate may increase the film deposition rate, the film quality may be insufficient to provide the desired etch characteristics without depositing extra carbon hard mask layer to produce a thicker overall layer and provide no reduction in the time to produce the layer.

Another way to deposit the layer more quickly is to inhibit etching of the AHM during deposition. A contributor to the deposition rate is a competitive etching process that occurs during the deposition process. Generally, the carbon precursors can generate hydrogen radicals or ions that may interact with carbon atoms depositing on the surface of the hard mask, leading to the generation of, for example, methane or other volatile products, ultimately etching the carbon mask and slowing the net deposition rate.

The present inventors have discovered that adding certain reactants to the process gas, herein referred to as “deposition enhancer molecules,” such as sulfur hexafluoride (SF₆), decreases the rate of the etching process, leading to a net increase in the deposition rate. Without being bound by theory, it is believed the SF₆ may react with the carbon precursors and/or hydrogen radicals to form SF₅ and HF, which may be exhausted from the process chamber without etching the hard mask. The production of HF reduces the presence of hydrogen radicals, inhibiting the competing etch process and thus increasing the overall rate of deposition.

The present inventors have also found that SF₆ may increase the consumption of the carbon precursor, increasing the generation of carbon ions that ultimately deposit into the resulting film. Table 1, below, illustrates the effect of SF₆ on the deposition rate and various film properties.

TABLE 1
Illustrating how SF₆ affects the deposition rate and AHM film properties.

| SF6 | | | | | | | |
|---|---|---|---|---|---|---|---|
| Flow | Dep. Rate | | Cntr. RI | Cntr. k | Stress | Hardness | Modulus |
| (sccm) | (Å/min) | R/2 NU % | @633 nm | @633 nm | (MPa) | (GPa) | (GPa) |
| 0 | 3525 | 8.0 | 2.065 | 0.44 | −145 | 5.3 (±0.1) | 50.4 (±0.5) |
| 100 | 4520 | 6.4 | 2.112 | 0.44 | −105 | 5.1 (±0.1) | 45.3 (±0.5) |
| 200 | 4825 | 3.7 | 2.150 | 0.41 | −105 | 4.8 (±0.1) | 43.2 (±0.5) |
| 300 | 6060 | 72.5 | 2.056 | 0.54 | NA | 5.1 (±0.1) | 43.6 (±0.5) |

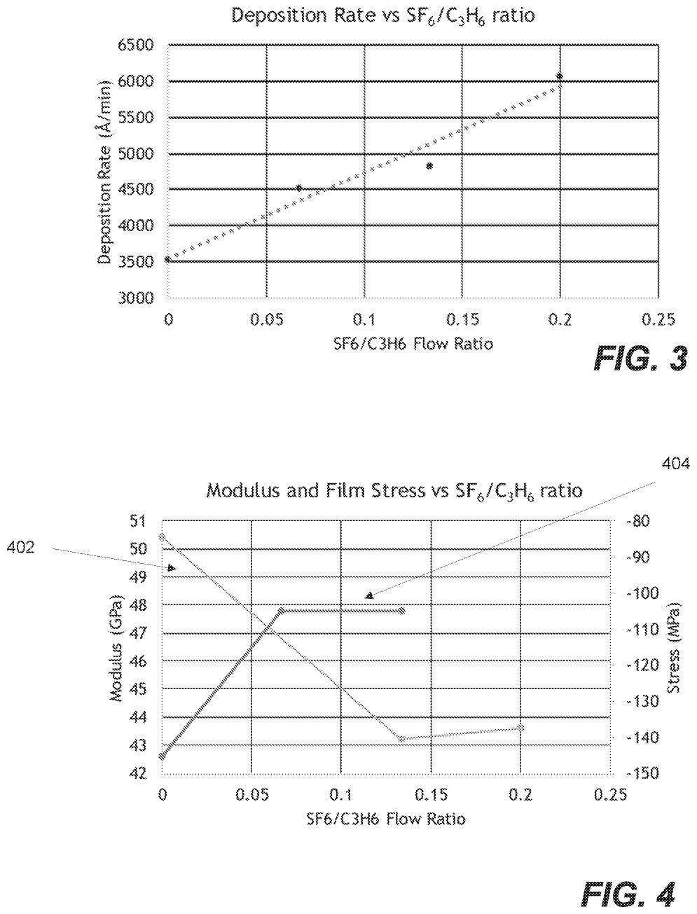

As shown in the table above, increasing the flow of SF₆ from 0 to 200 sccm results in about a 37% increase in deposition rate, with a decrease in modulus and hardness by about 15% and 10% respectively. SF₆ flow of 300 sccm results in a further increase in deposition rate, but at a significant decrease in half-range uniformity (R/2 NU %) and increase in extinction coefficient k. While 300 sccm flow of SF₆ result in high non-uniformity, this is believed to be a result of limitations of the tool that the experiment was performed on, and that 300 sccm or higher flows of SF₆ may be used to further increase the deposition rate with a resulting film having similar uniformity as below 300 sccm, with appropriate modifications as understood to a person of skill in the art. Other process conditions for all deposited films of the above table include: pedestal temperature of 550° C., pressure of 5 Tor, flow of 1500 sccm C₃H₆, 6000 W at 13.56 MHz, and 3450 W at 400 kHz. FIG. 3 presents a chart of deposition rate as a function of SF₆ to C₃H₆ flow ratio based on Table 1. As the proportion of SF₆ in the process gas increases, the flow rate increases, which is desirable.

### Process Window

In various embodiments, a rate boosting additive is added to the process gas during deposition of an amorphous carbon film. In some embodiments, the rate boosting additive is sulfur hexafluoride. In certain embodiments, a deposition process includes sulfur hexafluoride and propylene in a volumetric (approximately molar) ratio of about 0.01 to about 0.5. In certain embodiments, a deposition process includes sulfur hexafluoride and propylene in a volumetric (approximately molar) ratio of about 0.05 to about 0.15.

In certain embodiments, a deposition process includes an inert or chemically unreactive gas (e.g., Ar, He, and/or N₂) and propylene in a volumetric (approximately molar) ratio of about 0.03 to about 0.5. In certain embodiments, a deposition process includes an inert or chemically unreactive gas and propylene in a volumetric (approximately molar) ratio of about 0.15 to about 0.25.

In certain embodiments, the deposition process gas has about 3% to about 50% propylene or other hydrocarbon precursor, about 0.3 to about 25% sulfur hexafluoride, and about 25 to about 97.7% inert or chemically unreactive gas. All percentages are by volume or molar. In certain embodiments, the deposition process gas has about 15% to about 25% propylene or other hydrocarbon precursor, about 1.5 to about 12.5% sulfur hexafluoride, and about 62.5% to about 83.5% inert or chemically unreactive gas. In certain embodiments, the inert or chemically unreactive gas is argon, nitrogen, and/or helium

In some embodiments, the process gas consists of propylene and/or other carbon-containing precursors, inert gas, and hexafluoride. In some embodiments, the process gas consists essentially of propylene and/or other carbon-containing precursors, inert gas, and hexafluoride.

In some embodiments, the hydrocarbon precursor is one defined by the formula CₓH_{y}, wherein X is an integer between 2 and 10, and Y is an integer between 2 and 24. Examples include methane (CH₄), acetylene (C₂H₂), ethylene (C₂H₄), propylene (C₃H₆), butane (C₄H₁₀), cyclohexane (C₆H₁₂), benzene (C₆H₆), and toluene (C₇H₈). In certain embodiments, the process gas includes propylene alone or optionally in combination with one or more additional hydrocarbon precursors. In certain embodiments the hydrocarbon precursor is a halogenated hydrocarbon, where one or more hydrogen atoms are replaced by a halogen, particularly fluorine, chlorine, bromine, and/or iodine. In some embodiments the hydrocarbon precursor has a ratio of C:H of at least 1:2. In some embodiments, two or more hydrocarbon precursors may be used. In some embodiments, the hydrocarbon precursor may be an alkene, e.g., propylene. In some embodiments, the hydrocarbon precursor may be an alkyne, e.g., acetylene.

While the specification primarily identifies SF₆ as a deposition enhancer molecule for AHM films, in some embodiments, a deposition enhancer molecule is a hypervalent halogen compound. In some embodiments, a deposition enhance molecule is a hypervalent fluoride or hypervalent chloride. Hypervalent flourides and hypervalent chlorides may include hypervalent sulfur flourides (SF₆, SF₅), hypervalent phosphorous chlorides or hypervalent flourides (e.g., PCIs or PFs), and xenon flourides (e.g., XeF₂, XeF₄, XeF₆). In some embodiments, rather than SF₆ or in addition to SF₆, the process gas may include one or more of: hypervalent phosphorous chlorides or hypervalent flourides, or xenon flourides (it should be noted that xenon flourides, as a noble gas compound, may be considered a hypervalent compound as xenon starts with 8 electrons). In some embodiments, a deposition enhancer molecule is selected from the group consisting of: SF₆, hypervalent phosphorous chlorides or flourides, xenon fluorides, and any combinations thereof. In some embodiments, the deposition enhance molecule may be a fluorine-containing compound or a chlorine-containing compound. In some embodiments, a deposition enhancer molecule reacts with hydrogen ions and/or radicals during deposition of an AHM film. The deposition enhancer molecule may reduce a competing hydrogen etch process as described herein while not substantially depositing any species in the AHM film.

In some embodiments, the pressure in the process chamber may be about 1 to about 15 Torr, about 2.3 to about 10.7 Torr, or about 5 Torr typical. In some embodiments, the high frequency (13.56 MHz power) may be about 50 to about 8000 W, about 400 to about 4000 W, or about 6000 W, for a four station configuration. In some embodiments, the low frequency (400 kHz power) may be about 0 to about 6000 W, about 900 to about 4000 W, or about 3450 W, for a four-station configuration.

It has been observed in other contexts that the higher the deposition temperature, the less hydrogen present in the amorphous carbon film. Because lower amounts of hydrogen are desirable for hard mask applications, the temperature is often made as high as possible. In some embodiments, the pedestal temperature may be about 20° C. to about 750° C., or at most about 650° C., or about 550° C. to about 650° C., or about 650° C. In certain embodiments, it is at least about 400° C., or at least about 450° C. In certain embodiments, it is at least about 500° C. It is been observed that temperatures much higher than 650° C. may produce undesirable plasma results such as arcing in the chamber.

The film deposited for should be relatively uniform over the face of the wafer. The relative amount of uniformity or nonuniformity in the deposited film is a strong function of the process conditions used to deposit the amorphous carbon layer, rather than necessarily an intrinsic property of the amorphous carbon layer's composition.

### Process Mechanism

While not wishing to be bound by theory, it is believed that the deposition rate of amorphous carbon layers from a carbon containing precursor is impacted by at least two pathways.

A first pathway involves activation of the carbon precursor, e.g., propylene, by stripping off at least one hydrogen atom. It is believed that most likely acetylene is a reaction intermediate. In other words, in some manner, the propylene is converted to acetylene. Thereafter, the acetylene reacts to produce the amorphous carbon layer on a substrate surface.

A second pathway that influences the deposition rate is a competing etch process in which hydrogen radicals and/or hydrogen ions produced in a plasma interact with the depositing carbon film and form carbon-hydrogen bonds. When enough hydrogen attaches to a given carbon atom, it forms volatile methane, or other light hydrocarbons, which flows out of the chamber, taking with it a carbon atom that would otherwise be used to build up the amorphous carbon hard mask.

Therefore, the deposition of an amorphous carbon hard mask is a balance between the deposition pathway from propylene to the amorphous carbon and a competing hydrogen-mediated etch reaction.

While not wishing to be bound by theory, it is believed that sulfur hexafluoride impacts both of these pathways. It appears to react with hydrogen in the plasma and form hydrogen fluoride that does not etch the growing film. HF is also not considered a depositing species as fluorine is not found in the resulting film by RBS or solid state FTIR. Therefore, the presence of sulfur hexafluoride may reduce the competing hydrogen-mediated etch process.

Somewhat surprisingly in this regard, it is been found that the sulfur hexafluoride does not itself etch or at least significantly etch the depositing amorphous carbon film. Sulfur hexafluoride is widely used as an etchant gas in the integrated circuit fabrication industry. Surprisingly, it is been found that in the absence of a depositing carbon layer, sulfur hexafluoride and propylene, the process gas desired to be used herein, react to form carbon hexafluoride. This result might suggest that, sulfur hexafluoride, which is a widely used etchant gas, would react with the forming amorphous carbon hard mask and etch it. However, this is not the case.

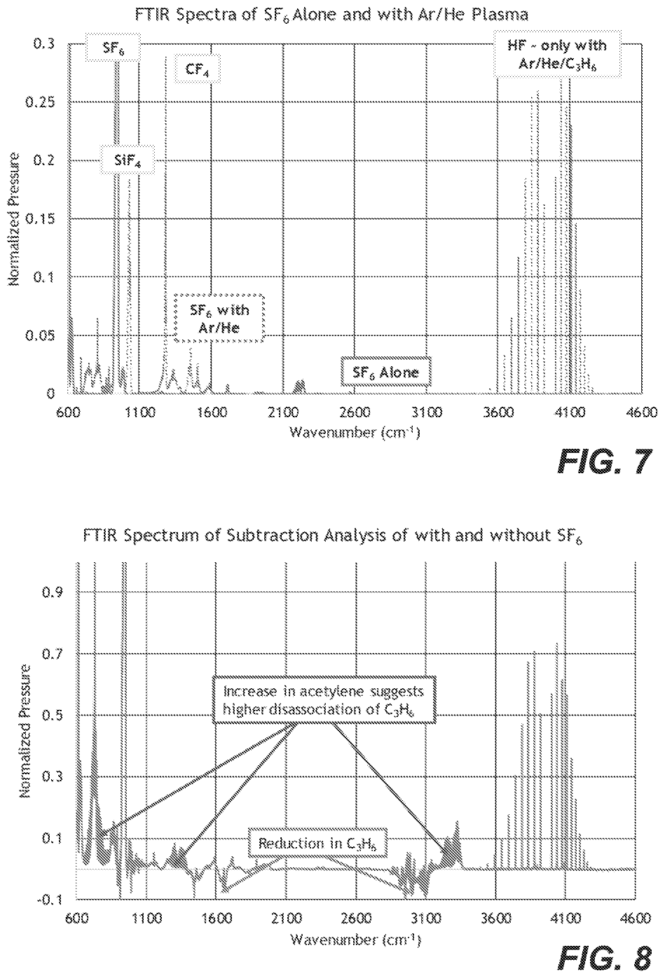

FIG. 7 presents overlaid gas-phase FTIR spectra for SF₆ alone (solid lines) and SF₆ with Ar/He (dotted lines). The large peak around 1000 for SF₆ alone, as well as the absence of peaks elsewhere, indicates that SF₆ alone does not dissociate in the presence of plasma.

The dotted lines represent SF₆ with Ar/He, and the numerous peaks above 3600 represent generation of HF, indicating SF₆ will dissociate in the presence of a carrier gas, such as argon, helium, nitrogen, or C₃H₆, which C₃H₆ may dissociate in plasma into ions or reactive neutrals.

Furthermore, there are peaks signaling that SiF₄ and CF₄ were generated. The inventors believe the presence of SiF₄ and CF₄ result from residual carbon and silicon remaining in the chamber where this experiment was performed. The presence of such products, as well as HF, additionally indicate that the SF₆ dissociated in the presence of argon and helium plasma. The presence of SiF₄ and CF₄ also indicate an etch process, which SF₆ is commonly used for and would normally be undesirable for an AHM deposition. Based on this alone, this spectrum would indicate that SF₆ would etch carbon from an AHM film during deposition.

FIG. 8 presents a gas-phase FTIR spectra for C₃H₆ with Ar/He subtracted from a gas-phase FTIR spectra for C₃H₆ with Ar/He and SF₆. Positive intensities indicate an increase in the chemical species with introduction of SF₆, while negative intensities indicate a decrease in the chemical species. Unexpectedly, adding SF₆ did not result in etching of the film, as already shown in Table 1, above. Adding SF₆ decreased the amount of C₃HF, indicating greater consumption of propylene. This may be caused by the propylene dissociating in the plasma to form reactive neutrals of C₃H₅ and hydrogen, which react with SF₆ to form HF. The SF₆ acts as a sink to consume hydrogen, causing the increase in HF represented by the peaks above 3600. As SF₆ has a large peak in the spectra of FIG. 8, it also may not be completely consumed during the deposition process.

Furthermore, positive peaks associated with acetylene suggest greater consumption of propylene. Acetylene is considered an intermediate product from propylene during deposition and can be easily tracked in an exhaust line when taking FTIR readings. Thus, while acetylene may be converted to a depositing species, its presence is indicative of increased dissociation of C₃H₆, which indicates an increased deposition rate.

Furthermore, while SF₆ and Ar/He showed peaks associated with SiF₄ and CF₄, see FIG. 7, here there are no such peaks. This is thought to result from the hydrogen radicals and ions from the propylene reacting with the SF₆ to form HF, inhibiting the fluorine from etching carbon or silicon to form SiF₄ or CF₄. Thus, while the spectra of FIG. 7 would indicate that SF₆ would etch the carbon film, FIG. 8 demonstrates that in the presence of propylene the SF₆ does not produce CF₄ and thus inhibits etching of the film rather than increasing etching.

### Film Properties

High aspect ratio patterning uses AHMs having high etch selectivity. Importantly, increasing the deposition rate while maintaining etch selectivity allows for a lower cost of ownership for an AHM film used in IC fabrication, which is desirable. In some embodiments, the deposition rate is at least about 3500 Å/min, at least about 4500 Å/min, or about 3500 to about 6000 Å/min.

Etch selectivity can be determined by comparing the etch rate of the AHM layer to an underlying layer. The etch selectivity can sometimes be approximated by determining the hydrogen content, refractive index (RI), density, and Young's modulus, or rigidity, of the AHM layer. Typically, lower hydrogen content, higher RI, higher density, and higher modulus, or a more rigid, AHM is able to withstand higher etch rates in an etch process involving more ion bombardment. Therefore, AHMs with lower hydrogen content, higher RI, higher density, and/or higher modulus have higher selectivity and lower etching rate and can be used more efficiently and effectively for processing high aspect ratio semiconductor processes. The desired etch selectivity of the AHM may depend on the etching process and the composition of the underlying layers, but the correlation between etch selectivity and the material properties above remains the same regardless of the etching process or composition of the underlying layers. The selectivity correlations as described here applies to all types of underlying layers, including polysilicon layers, oxide layers, and nitride layers.

AHM films produced in accordance with the disclosed methods are typically composed primarily of carbon and hydrogen, but other elements may be present in the film. In some embodiments the carbon concentration is at least about 70 percent atomic. Examples of other elements that may be present in the AHM film include halogens, nitrogen, sulfur, boron, oxygen, tungsten, titanium, and aluminum. Typically, such other elements are present in amounts not greater than about 10 percent atomic. In some embodiments, the hydrogen concentration is at most about 28% atomic, at most about 25% atomic, or at most about 10% atomic.

The deposited amorphous carbon layer should have a relatively high density. In certain embodiments, an amorphous carbon layer has a density of about 1.65 to about 1.85 g/cm3. In certain embodiments, an amorphous carbon layer has a hardness of about 5.0 to about 8.5 GPa.

While density is defined in units of mass per volume, direct measurements of density are not always easily available. However, in some cases, more easily measurable properties may serve as a proxy for density. One such property is modulus. In some embodiments, an amorphous carbon layer has a modulus between about 40 to about 90 GPa, about 60 to about 85 GPa, or about 90 to about 175 GPa.

A relatively low internal stress of the deposited amorphous carbon layer is suitable for various embodiments. A relatively low internal stress suggests that the film is less likely to introduce bow or warpage into the wafer. In certain embodiments, an amorphous carbon layer has an internal stress of about −100 to about −550 MPa or about −75 to about −150 MPa (negative is compressive).

In certain embodiments, an amorphous carbon layer has a relatively high content of graphite-like carbon in comparison to diamond-like carbon. It should have relatively high bond content of sp² bonds in comparison to sp³ bonds. In certain embodiments, an amorphous carbon layer has an sp² content of about 5% to about 30% or about 10% to about 15%, with the rest of the amorphous carbon layer having diamond-like sp³ bonds.

The amorphous carbon layer may be characterized by its extinction coefficient, k, in the optical region of the EM spectrum. The extinction coefficient may be a proxy for the relative amounts of sp² and sp³ bonds. A relatively high extinction coefficient suggests a darker, opaque, material at the wavelength of measurement. In other words, a relatively high extinction coefficient at 633 nm suggests a relatively high content of graphitic content in the film. In some embodiments, the extinction coefficient is about 0.40 to about 0 70 or about 0.45 to about 0.65. In certain embodiments, an amorphous carbon layer has a refractive index of about 1.9 to about 2.2 or 2.0 to about 2.1.

### EXAMPLES

FIG. 4-6 present various charts showing the change in properties of a deposited amorphous carbon film as SF₆ flow ratio increases. The values in FIGS. 4-6 are from Table 1, above.

FIG. 4 presents a chart of modulus 402 and stress 404 as a function of SF₆ to C₃H₆ flow ratio. Generally, higher modulus is desirable, however the −8 GPa decrease in modulus is considered modest and acceptable for the increase in deposition rate to reduce the overall cost of ownership for an AHM. Furthermore, the stress of the films becomes slightly more neutral with SF₆, which is generally desirable to reduce warping of the AHM that would decrease line uniformity.

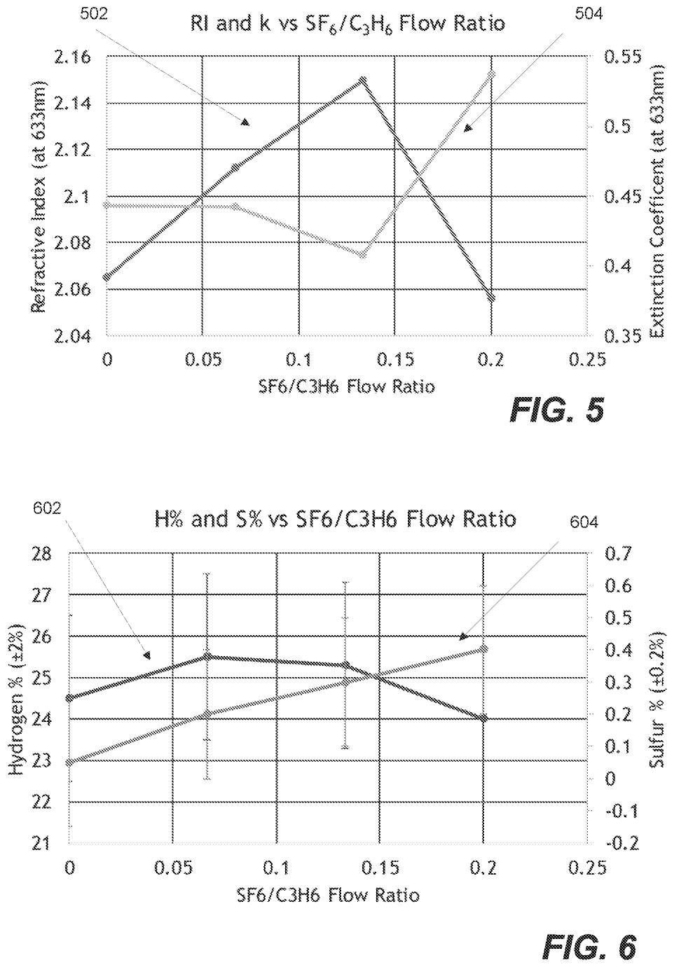

FIG. 5 presents a chart of refractive index 502 and extinction coefficient 504 as a function of SF₆ to C₃H₆ flow ratio. Generally, the change in refractive index is considered nominal and within error, thus the addition of SF₆ does not significantly increase refractive index. Extinction coefficient, similarly, has a slight change as SF₆ is added to the process gas flow, but SF₆ does not significantly increase the extinction coefficient.

FIG. 6 presents a chart of hydrogen content 602 and sulfur content 604 as a function of SF₆ to C₃H₆ flow ratio. As may be apparent, all of the measured values for hydrogen content are within the standard of error, which indicates the presence of SF₆ increases the deposition rate without increasing the hydrogen content of the resulting film, which is desirable. Sulfur content, on the other hand, does increase by about 0.1% per 100 sccm increase in SF₆, however this change is considered to not affect the resulting film's etch selectivity.

As illustrated by FIGS. 4-6, when we add SF₆, modulus and stress decrease. More neutral stress is beneficial to reduce warping. Modulus and hydrogen content are strongly correlated for film performance, but at lower hydrogen content, such as the films described herein, modulus does not correlate with etch selectivity as strongly as at higher hydrogen content.

Refractive index is a proxy for density, as it indicates, among other things, the amount of transparent, diamond-like sp³ bonds compared to opaque, graphite-like sp² bonds. Here, the change in RI is within an acceptable range for film properties. Extinction coefficient correlates with an amount of graphite like and diamond like bonds in the film. Hydrogen or sulfur content in the film decreases the extinction coefficient.

### Apparatus

Embodiments can be implemented in a plasma enhanced chemical vapor deposition (PECVD) reactor. Such a reactor may take many different forms. Various embodiments are compatible with existing semiconductor processing equipment—in particular, PECVD reactors such as Sequel™ or Vector™ reactor chambers available from Lam Research Corporation. The various embodiments may be implemented on a multi-station or single station tool. In specific embodiments, the 300 mm Lam Vector™ tool having a 4-station deposition scheme or the 200 mm Sequel™ tool having a 6-station deposition scheme are used. Process parameters described herein are for a 4-station chamber depositing on 300 mm substrates, but suitable adjustments may be used for more or fewer stations and larger or smaller substrates.

Generally, the apparatus will include one or more chambers or reactors that each include one or more stations. Chambers will house one or more wafers and are suitable for wafer processing. The one or more chambers maintain the wafer in a defined position or positions, by preventing rotation, vibration, or other agitation. In some embodiment, a wafer undergoing AHM deposition is transferred from one station to another within a chamber during the process. For example, a 2000 nm AHM deposition may occur entirely at one station, or 500 nm of film may be deposited at each of four stations in accordance with various embodiments. Alternatively, any other fraction of the total film thickness may be deposited at any number of stations. In various embodiments where more than one AHM is deposited, more than one station may be used to deposit each AHM layer. During processing, each wafer is held in place by a pedestal, wafer chuck, and/or other wafer holding apparatus. For certain operations where the wafer is to be heated, the apparatus may include a heater such as a heating plate.

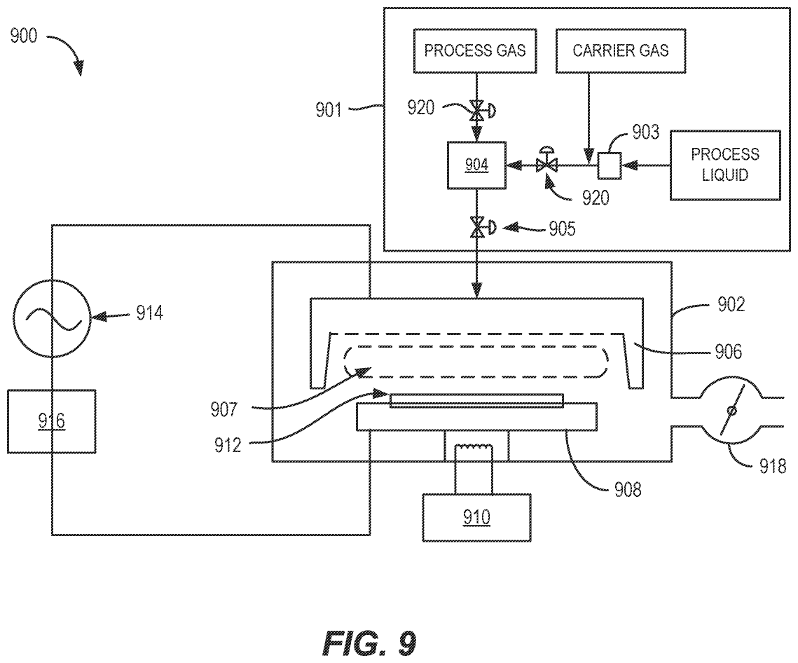

FIG. 9 schematically shows an embodiment of a process station 900 that may be used to deposit material using plasma enhanced chemical vapor deposition (PECVD). For simplicity, the process station 900 is depicted as a standalone process station having a process chamber body 902 for maintaining a low-pressure environment. However, it will be appreciated that a plurality of process stations 900 may be included in a common process tool environment. Further, it will be appreciated that, in some embodiments, one or more hardware parameters of process station 900, including those discussed in detail below, may be adjusted programmatically by one or more computer controllers.

Process station 900 fluidly communicates with reactant delivery system 901 for delivering process gases to a distribution showerhead 906. Reactant delivery system 901 includes a mixing vessel 904 for blending and/or conditioning process gases for delivery to showerhead 906. One or more mixing vessel inlet valves 920 may control introduction of process gases to mixing vessel 904. Similarly, a showerhead inlet valve 905 may control introduction of process gasses to the showerhead 906.

For example, the embodiment of FIG. 9 includes a vaporization point 903 for vaporizing liquid reactant to be supplied to mixing vessel 904. In some embodiments, vaporization point 903 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 903 may be heat traced. In some examples, mixing vessel 904 may also be heat traced. In one non-limiting example, piping downstream of vaporization point 903 has an increasing temperature profile extending from approximately 100° C. to approximately 150° C. at mixing vessel 904.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 903. In one scenario, a liquid injector may be mounted directly to mixing vessel 904. In another scenario, a liquid injector may be mounted directly to showerhead 906.

In some embodiments, a liquid flow controller upstream of vaporization point 903 may be provided for controlling a mass flow of liquid for vaporization and delivery to process station 900. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 906 distributes process gases toward substrate 912. In the embodiment shown in FIG. 9, substrate 912 is located beneath showerhead 906, and is shown resting on a pedestal 908. It will be appreciated that showerhead 906 may have any suitable shape, and may have any suitable number and arrangement of ports for distributing processes gases to substrate 912.

In some embodiments, a microvolume 907 is located beneath showerhead 906. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 908 may be raised or lowered to expose substrate 912 to microvolume 907 and/or to vary a volume of microvolume 907. For example, in a substrate transfer phase, pedestal 908 may be lowered to allow substrate 912 to be loaded onto pedestal 908. During a deposition process phase, pedestal 908 may be raised to position substrate 912 within microvolume 907. In some embodiments, microvolume 907 may completely enclose substrate 912 as well as a portion of pedestal 908 to create a region of high flow impedance during a deposition process.

Optionally, pedestal 908 may be lowered and/or raised during portions the deposition process to modulate process pressure, reactant concentration, etc., within microvolume 907. In one scenario where process chamber body 902 remains at a base pressure during the deposition process, lowering pedestal 908 may allow microvolume 907 to be evacuated. Example ratios of microvolume to process chamber volume include, but are not limited to, volume ratios between 1:900 and 1:10. It will be appreciated that, in some embodiments, pedestal height may be adjusted programmatically by a suitable computer controller.

In another scenario, adjusting a height of pedestal 908 may allow a plasma density to be varied during plasma activation and/or treatment cycles included in the deposition process. At the conclusion of the deposition process phase, pedestal 908 may be lowered during another substrate transfer phase to allow removal of substrate 912 from pedestal 908.

While the example microvolume variations described herein refer to a height-adjustable pedestal, it will be appreciated that, in some embodiments, a position of showerhead 906 may be adjusted relative to pedestal 908 to vary a volume of microvolume 907. Further, it will be appreciated that a vertical position of pedestal 908 and/or showerhead 906 may be varied by any suitable mechanism within the scope of the present disclosure. In some embodiments, pedestal 908 may include a rotational axis for rotating an orientation of substrate 912. It will be appreciated that, in some embodiments, one or more of these example adjustments may be performed programmatically by one or more suitable computer controllers.

Returning to the embodiment shown in FIG. 9, showerhead 906 and pedestal 908 electrically communicate with RF power supply 914 and matching network 916 for powering a plasma. In some embodiments, the plasma energy may be controlled by controlling one or more of a process station pressure, a gas concentration, an RF source power, an RF source frequency, and a plasma power pulse timing. For example, RF power supply 914 and matching network 916 may be operated at any suitable power to form a plasma having a desired composition of radical species. Examples of suitable powers are included above. Likewise, RF power supply 914 may provide RF power of any suitable frequency. In some embodiments, RF power supply 914 may be configured to control high- and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a hydrocarbon precursor gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 908 may be temperature controlled via heater 910. Further, in some embodiments, pressure control for deposition process station 900 may be provided by butterfly valve 918. As shown in the embodiment of FIG. 9, butterfly valve 918 throttles a vacuum provided by a downstream vacuum pump (not shown). However, in some embodiments, pressure control of process station 900 may also be adjusted by varying a flow rate of one or more gases introduced to process station 900.

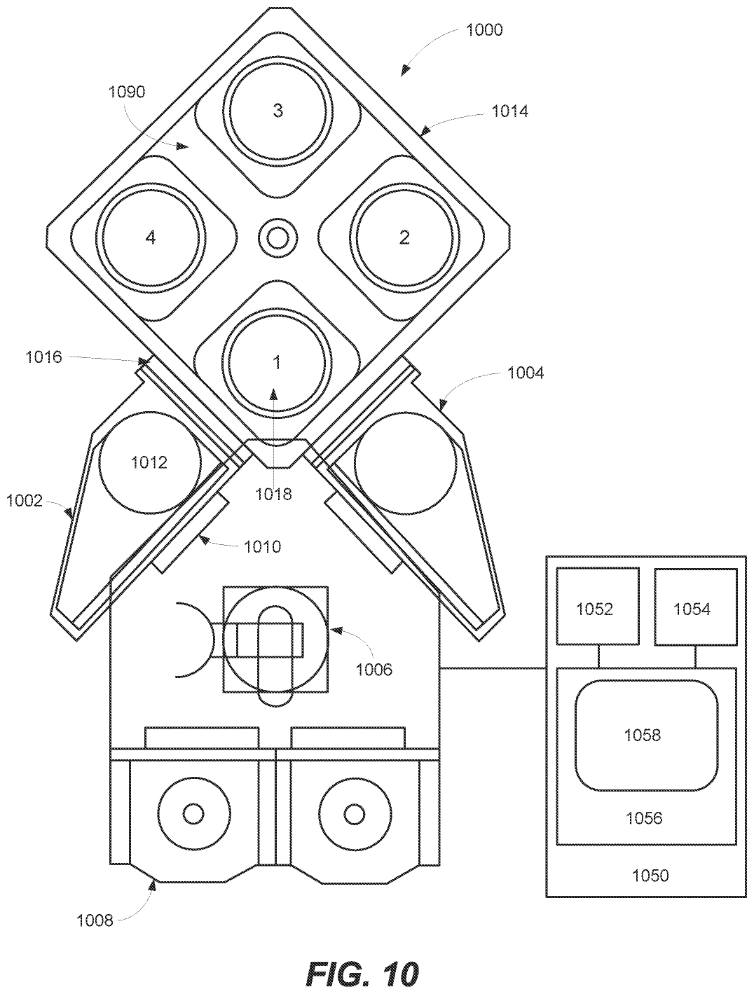

FIG. 10 shows a schematic view of an embodiment of a multi-station processing tool 1000 with an inbound load lock 1002 and an outbound load lock 1004, either or both of which may comprise a remote plasma source. A robot 1006, at atmospheric pressure, is configured to move wafers from a cassette loaded through a pod 1008 into inbound load lock 1002 via an atmospheric port 1010. A wafer is placed by the robot 1006 on a pedestal 1012 in the inbound load lock 1002, the atmospheric port 1010 is closed, and the load lock is pumped down. Where the inbound load lock 1002 comprises a remote plasma source, the wafer may be exposed to a remote plasma treatment in the load lock prior to being introduced into a processing chamber 1014. Further, the wafer also may be heated in the inbound load lock 1002 as well, for example, to remove moisture and adsorbed gases. Next, a chamber transport port 1016 to processing chamber 1014 is opened, and another robot (not shown) places the wafer into the reactor on a pedestal of a first station shown in the reactor for processing. While the embodiment depicted in FIG. 10 includes load locks, it will be appreciated that, in some embodiments, direct entry of a wafer into a process station may be provided.

The depicted processing chamber 1014 comprises four process stations, numbered from 1 to 4 in the embodiment shown in FIG. 10. Each station has a heated pedestal (shown at 1018 for station 1), and gas line inlets. It will be appreciated that in some embodiments, each process station may have different or multiple purposes. While the depicted processing chamber 1014 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 10 also depicts an embodiment of a wafer handling system 1090 for transferring wafers within processing chamber 1014. In some embodiments, wafer handling system 1090 may transfer wafers between various process stations and/or between a process station and a load lock. It will be appreciated that any suitable wafer handling system may be employed. Non-limiting examples include wafer carousels and wafer handling robots. FIG. 10 also depicts an embodiment of a system controller 1050 employed to control process conditions and hardware states of process tool 1000. System controller 1050 may include one or more memory devices 1056, one or more mass storage devices 1054, and one or more processors 1052. Processor 1052 may include a CPU or computer, analog and/or digital input/output connections, stepper motor controller boards, etc.

In some embodiments, system controller 1050 controls all of the activities of process tool 1000. System controller 1050 executes system control software 1058 stored in mass storage device 1054, loaded into memory device 1056, and executed on processor 1052. System control software 1058 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 1000. System control software 1058 may be configured in any suitable way. For example, various process tool component subroutines or control objects may be written to control operation of the process tool components necessary to carry out various process tool processes in accordance with the disclosed methods. System control software 1058 may be coded in any suitable computer readable programming language.

In some embodiments, system control software 1058 may include input/output control (IOC) sequencing instructions for controlling the various parameters described above. Other computer software and/or programs stored on mass storage device 1054 and/or memory device 1056 associated with system controller 1050 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 1018 and to control the spacing between the substrate and other parts of process tool 1000.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 1050. The user interface may include a display screen, graphical software displays of the apparatus and/or process conditions, and user input devices such as pointing devices, keyboards, touch screens, microphones, etc.

In some embodiments, parameters adjusted by system controller 1050 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 1050 from various process tool sensors. The signals for controlling the process may be output on the analog and digital output connections of process tool 1000. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

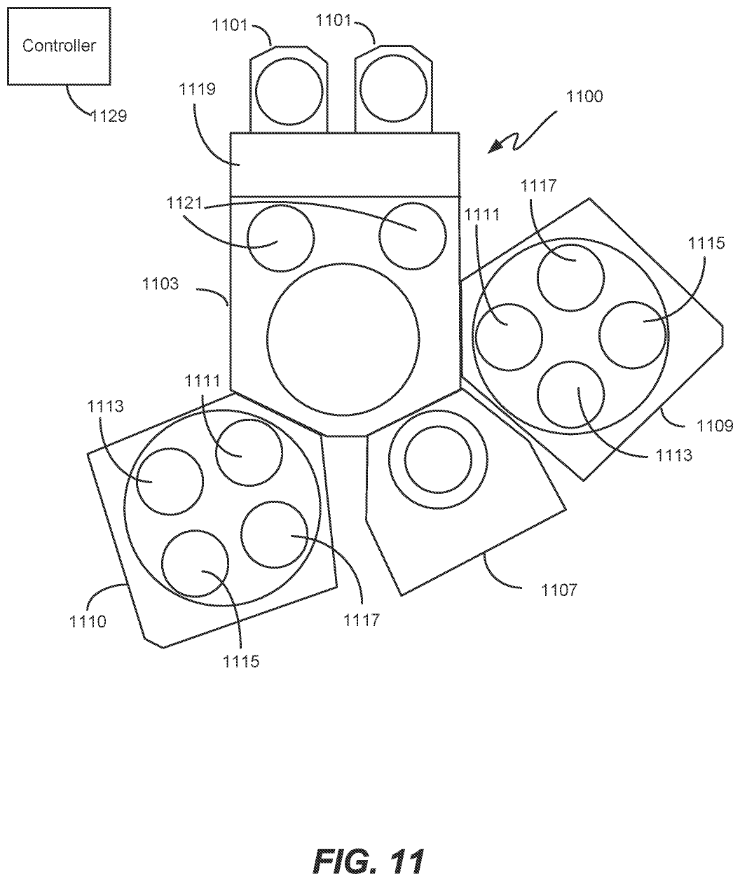

FIG. 11 is a block diagram of a processing system suitable for conducting thin film deposition processes in accordance with certain embodiments. The system 1100 includes a transfer module 1103. The transfer module 1103 provides a clean, pressurized environment to minimize risk of contamination of substrates being processed as they are moved between various reactor modules. Mounted on the transfer module 1103 are two multi-station reactors 1109 and 1110, each capable of performing atomic layer deposition (ALD) and/or chemical vapor deposition (CVD) according to certain embodiments. Reactors 1109 and 1110 may include multiple stations 1111, 1113, 1115, and 1117 that may sequentially or non-sequentially perform operations in accordance with disclosed embodiments. The stations may include a heated pedestal or substrate support, one or more gas inlets or showerhead or dispersion plate.

Also mounted on the transfer module 1103 may be one or more single or multi-station modules 1107 capable of performing plasma or chemical (non-plasma) pre-cleans, or any other processes described in relation to the disclosed methods. The module 1107 may in some cases be used for various treatments to, for example, prepare a substrate for a deposition process. The module 1107 may also be designed/configured to perform various other processes such as etching or polishing. The system 1100 also includes one or more wafer source modules 1101, where wafers are stored before and after processing. An atmospheric robot (not shown) in the atmospheric transfer chamber 1119 may first remove wafers from the source modules 1101 to loadlocks 1121. A wafer transfer device (generally a robot arm unit) in the transfer module 1103 moves the wafers from loadlocks 1121 to and among the modules mounted on the transfer module 1103.

In various embodiments, a system controller 1129 is employed to control process conditions during deposition. The controller 1129 will typically include one or more memory devices and one or more processors. A processor may include a CPU or computer, analog and/or digital input/output connections, stepper motor controller boards, etc.

The controller 1129 may control all of the activities of the deposition apparatus. The system controller 1129 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1129 may be employed in some embodiments.

Typically there will be a user interface associated with the controller 1129. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 1129. The signals for controlling the process are output on the analog and digital output connections of the deposition apparatus 1100.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 1129 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1129, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of forming an ashable hard mask (AHM) film, comprising:
exposing a substrate to a process gas comprising a hydrocarbon precursor gas and a deposition enhancer molecule; and
depositing on the substrate the AHM film by a plasma enhanced chemical vapor deposition (PECVD) process using the process gas.

2. The method of claim 1, wherein the deposition enhancer molecule is a fluorine-containing compound.

3. The method of claim 1, wherein the deposition enhancer molecule is SF₆.

4. The method of claim 1, wherein the hydrocarbon precursor gas comprises an alkene.

5. The method of claim 1, wherein the hydrocarbon precursor gas comprises propylene.

6. The method of claim 1, wherein the volumetric flow ratio of deposition enhancer molecule to hydrocarbon precursor is between about 0.01 to about 0.5.

7. The method of claim 1, wherein the AHM film is deposited at a rate greater than about 0.45 μm/min.

8. The method of claim 1, further comprising forming HF during depositing the AHM film.

9. The method of claim 1, wherein the process gas further comprises an inert gas.

10. The method of claim 9, wherein the inert gas is one or more of helium, argon, and nitrogen.

11. The method of claim 9, wherein the process gas comprises the hydrocarbon precursor gas, the deposition enhancer molecule, and the inert gas.

12. The method of claim 1, wherein the substrate is positioned on a pedestal while depositing the AHM film, and the pedestal has a temperature between about 20° C. and about 750° C.

13. The method of claim 1, wherein the deposition enhancer molecule inhibits an etch process resulting from hydrogen radicals, ions, or both bonding with carbon atoms in the deposited AHM film.

14. The method of claim 1, wherein the deposition enhancer molecule does not cause etching of the AHM film.

15. The method of claim 1, wherein the PECVD process comprises igniting a plasma generated by a dual radio frequency (RF) plasma source including a high frequency (HF) component and a low frequency (LF) component.

16. The method of claim 15, wherein the HF component has a power of about 50 to about 8000 W.

17. The method of claim 15, wherein the LF component has a power of about 0 to about 6000 W.

18. The method of claim 1, wherein the PECVD process is performed at a pressure of about 1 to about 11 Torr.

19. The method of claim 1, wherein the AHM film has a modulus of about 43 to about 90 GPa.

20. The method of claim 1, wherein the AHM film is between about 1 μm and about 2 μm thick.

21. The method of claim 1, wherein the AHM film has a hardness of about 5.3 to about 8.5 GPa.

22. The method of claim 1, wherein the AHM film has an internal stress of about −100 to about −550 MPa.

23. The method of claim 1, wherein the AHM film has an extinction coefficient of about 0.45 to about 0.65.

24. The method of claim 1, wherein the AHM film has a refractive index of about 1.9 to about 2.2.

25. The method of claim 1, wherein the AHM film comprises mostly carbon.

26. The method of claim 1, wherein the AHM film has a hydrogen content of at most about 10% atomic.

27. An apparatus for forming an ashable hard mask (AHM) film, comprising:
one or more process chambers, each process chamber comprising a substrate support;
one or more gas inlets into the process chambers and associated flow-control hardware; and
one or more processors configured to:
expose a substrate in one of the one or more process chambers to a process gas comprising a hydrocarbon precursor gas and a deposition enhancer molecule; and
deposit on the substrate the AHM film by a plasma enhanced chemical vapor deposition (PECVD) process using the process gas.
